(19) United States
(12) Patent Application Publication
(10) Pub. No.: US 2022/0128833 A1
(43) Pub. Date: Apr. 28, 2022

(54) APPARATUS WITH HALL SENSOR COMMON MODE VOLTAGE ADJUSTMENT AND APPARATUS WITH LENS MODULE CONTROL

(71) Applicant: SAMSUNG ELECTRO-MECHANICS CO., LTD., Suwon-si (KR)

(72) Inventor: Yo Sub MOON, Suwon-si (KR)

(73) Assignee: SAMSUNG ELECTRO-MECHANICS CO., LTD., Suwon-si (KR)

(21) Appl. No.: 17/182,305

(22) Filed: Feb. 23, 2021

(30) Foreign Application Priority Data
Oct. 23, 2020 (KR) 10-2020-0137985

(51) Int. Cl. G02B 27/64; H03F 3/45; G05F 3/20; G01D 5/14

(52) U.S. Cl. CPC G02B 27/646; G01D 5/142; G05F 3/20; H03F 3/45071

(57) ABSTRACT

An apparatus with hall sensor common mode voltage adjustment includes: a bias provider configured to provide a bias current to the hall sensor; a first voltage regulator configured to vary a first voltage difference between the hall sensor and the bias provider, based on the bias current; and a second voltage regulator configured to vary a second voltage difference between the hall sensor and a ground, based on the bias current. The first and second voltage differences are variable such that a difference between the first voltage difference and the second voltage difference corresponds to a difference between a common mode voltage of first and second hall sensor output terminals of the hall sensor and a reference voltage.

### CROSS-REFERENCE TO RELATED APPLICATION

This application claims the benefit under 35 U.S.C. §119(a) of Korean Patent Application No. 10-2020-0137985 filed on Oct. 23, 2020 in the Korean Intellectual Property Office, the entire disclosure of which is incorporated herein by reference for all purposes.

### BACKGROUND

### 1. Field

The following description relates to an apparatus for adjusting a common mode voltage of a hall sensor and an apparatus for controlling a lens module.

### 2. Description of Related Art

In general, when a lens module moves according to external force, a technology for fixing a relative position of the lens module with respect to the structure outside of the lens module is widely used.

For example, the camera module may include an optical image stabilizer that fixes the position of the lens module inside camera module even when receiving external force.

A hall sensor may be used to measure position information of a lens module, and the hall sensor may output a voltage varying according to the position of the lens module. The accuracy of the optical image stabilization may increase as the accuracy of the correspondence between the output voltage of the hall sensor and the position information of the lens module increases.

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

In one general aspect, an apparatus with hall sensor common mode voltage adjustment includes: a bias provider configured to provide a bias current to a hall sensor; a first voltage regulator configured to vary a first voltage difference between the hall sensor and the bias provider, based on the bias current; and a second voltage regulator configured to vary a second voltage difference between the hall sensor and a ground, based on the bias current. The first and second voltage differences are variable such that a difference between the first voltage difference and the second voltage difference corresponds to a difference between a common mode voltage of first and second hall sensor output terminals of the hall sensor and a reference voltage.

The first and second voltage differences may be variable such that a value obtained by subtracting the second voltage difference from the first voltage difference increases as the common mode voltage of the of first and second hall sensor output terminals increases.

The apparatus may further include an amplifier configured to amplify a voltage difference between the first and second hall sensor output terminals. The amplifier may include: a first amplifier including a first amplifier output terminal, a first amplifier input terminal electrically connected to the first amplifier output terminal, and another first amplifier input terminal electrically connected to the first hall sensor output terminal; a second amplifier including a second amplifier output terminal, a second amplifier input terminal electrically connected to the second amplifier output terminal, another second amplifier input terminal electrically connected to the second hall sensor output terminal; and a third amplifier including a third amplifier output terminal, a third amplifier input terminal electrically connected to the second amplifier output terminal, and another third amplifier input terminal electrically connected to the first amplifier output terminal and the third amplifier output terminal.

The apparatus may further include: an amplifier configured to amplify a voltage difference between the first and second hall sensor output terminals; and a common mode controller configured to control the first and second voltage differences, based on a voltage of either one or both of a node between the first hall sensor output terminal and the amplifier, and a node between the second hall sensor output terminal and the amplifier.

The apparatus may further include a common mode controller configured to control the first and second voltage differences, based on the common mode voltage of the first and second hall sensor output terminals.

The common mode controller may be further configured to: determine a voltage difference to be changed, among the first voltage difference and the second voltage difference, according to a high and low relationship between the common mode voltage of the first and second hall sensor output terminals and the reference voltage; and stepwise adjust a voltage difference of a voltage regulator corresponding to a predetermined voltage difference, among the first and second voltage regulators.

The first voltage regulator may include at least one first resistor connected such that a resistance value between the hall sensor and the bias provider is variable. The second voltage regulator may include at least one second resistor connected such that a resistance value between the hall sensor and the ground is variable.

In another general aspect, an apparatus with lens module control includes: the apparatus with hall sensor common mode voltage adjustment described above; a driver configured to output a driving current, based on a voltage difference between the first and second hall sensor output terminals; a driving coil configured to receive the driving current; a lens module configured to move based on the driving current, as the driving current flows through the driving coil; and the hall sensor. The hall sensor is configured to determine the voltage difference between the first and second hall sensor output terminals, based on a position of the lens module.

The apparatus with lens module control may further include a processor configured to control first and second voltage differences of the first and second voltage regulators, based on the common mode voltage of first and second hall sensor output terminals.

The apparatus with lens module control may further include a processor configured to control the bias provider such that the bias current is variable and control first and second voltage differences, based on the bias current.

In another general aspect, an apparatus with hall sensor common mode voltage adjustment includes: a bias provider configured to provide a bias current to a hall sensor; a first voltage regulator configured to vary a first voltage difference between the hall sensor and the bias provider, based on the bias current; and a second voltage regulator configured to vary a second voltage difference between the hall sensor and a ground, based on the bias current. The first and second voltage differences are variable such that a difference between the first voltage difference and the second voltage difference corresponds to a difference between the bias current and a reference current.

The first and second voltage differences may be variable such that a value obtained by subtracting the second voltage difference from the first voltage difference increases as the bias current increases.

The apparatus may further include: an amplifier configured to amplify a voltage difference between first and second hall sensor output terminals of the hall sensor; and an AD converter electrically connected to an output terminal of the amplifier, and configured to convert an analog value into a digital value and output the digital value. The bias provider may be further configured to vary the bias current, based on the digital value.

The apparatus may further include an amplifier configured to amplify a voltage difference between first and second hall sensor output terminals of the hall sensor. The amplifier may include: a first amplifier including a first amplifier output terminal, a first amplifier input terminal electrically connected to the first amplifier output terminal, and another first amplifier input terminal electrically connected to the first hall sensor output terminal; a second amplifier including a second amplifier output terminal, a second amplifier input terminal electrically connected to the second amplifier output terminal, and another second amplifier input terminal electrically connected to the second hall sensor output terminal; and a third amplifier including a third amplifier output terminal, a third amplifier input terminal electrically connected to the second amplifier output terminal, another third amplifier input terminal electrically connected to the first amplifier output terminal and the third amplifier output terminal.

The first voltage regulator may include at least one first resistor connected such that a resistance value between the hall sensor and the bias provider is variable. The second voltage regulator may include at least one second resistor connected such that a resistance value between the hall sensor and the ground is variable.

The apparatus may further include a common mode controller configured to control the first and second voltage differences of the first and second voltage regulators. The at least one first resistor may include a plurality of first resistors. The at least one second resistor may include a plurality of second resistors. The common mode controller may be further configured to determine a voltage difference to be changed, among the first voltage difference and the second voltage difference, according to a high and low relationship between the bias current and the reference current, and stepwise activate a plurality of resistors corresponding to a predetermined voltage difference among the plurality of first resistors and the plurality of second resistors.

In another general aspect, an apparatus with lens module control includes: the apparatus with hall sensor common mode voltage adjustment described above; a driver configured to output a driving current, based on a voltage difference between the first and second hall sensor output terminals; a driving coil configured to receive the driving current; a lens module configured to move based on the driving current, as the driving current flows through the driving coil; and the hall sensor. The hall sensor is disposed to determine the voltage difference between the first and second hall sensor output terminals, based on a position of the lens module.

The apparatus with lens module control may further include a processor configured to control the first and second voltage differences, based on the common mode voltage of the first and second hall sensor output terminals.

The apparatus with lens module control may further include a processor configured to control the bias provider such that the bias current is variable and control first and second voltage differences, based on the bias current.

In another general aspect, an apparatus with hall sensor common mode voltage includes: a bias provider configured to provide a bias current to a hall sensor; a first voltage regulator configured to provide a first voltage difference between the hall sensor and the bias provider, based on the bias current; a second voltage regulator configured to provide a second voltage difference between the hall sensor and a ground, based on the bias current; and a controller configured to control either one or both of the first voltage regulator and the second voltage regulator to vary a difference between the first voltage difference and the second voltage difference, based on a common mode voltage of first and second hall sensor output terminals of the hall sensor.

The first voltage regulator may include a first variable resistance element and the second voltage regulator may include a second variable resistance element. The controller may be further configured to vary a total resistance of either one or both of the first variable resistance element and the second variable resistance element.

The first voltage regulator may include a first transistor and the second voltage regulator may include a second transistor. The controller may be further configured to vary either one or both of a control voltage applied to the first transistor and a control voltage applied the second transistor.

The controller may be further configured to control the first voltage regulator to increase the first voltage difference and/or control the second voltage regulator to decrease the second voltage difference, in response to the common mode voltage of first and second hall sensor output terminals increasing. The controller may be further configured to control the first voltage regulator to decrease the first voltage difference and/or control the second voltage regulator to increase the second voltage difference, in response to the common mode voltage of first and second hall sensor output terminals decreasing.

Other features and aspects will be apparent from the following detailed description, the drawings, and the claims.

### BRIEF DESCRIPTION OF DRAWINGS

FIG. 1 is a diagram illustrating an apparatus for adjusting a common mode voltage of a hall sensor, according to an example.

FIGS. 2A and 2B are diagrams illustrating control for first and second voltage regulators of apparatuses for adjusting a common mode voltage of a hall sensor, according to examples.

FIGS. 3A and 3B are diagrams illustrating voltage regulators of an apparatus for adjusting a common mode voltage of a hall sensor, according to an example.

FIG. 4 is a flowchart illustrating a control process for first and second voltage regulators of an apparatus for adjusting a common mode voltage of a hall sensor, according to an example.

FIG. 5 is a diagram illustrating an amplifier of an apparatus for adjusting a common mode voltage of a hall sensor, according to an example.

FIG. 6 is a graph illustrating a relationship between the amplifier illustrated in FIG. 5 and a common mode voltage, according to an example.

FIG. 7 is a view illustrating an apparatus for controlling a lens module, according to an example.

Throughout the drawings and the detailed description, the same reference numerals refer to the same elements. The drawings may not be to scale, and the relative sizes, proportions, and depictions of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Herein, it is to be noted that use of the term “may” with respect to an embodiment or example, e.g., as to what an embodiment or example may include or implement, means that at least one embodiment or example exists in which such a feature is included or implemented while all examples and examples are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as illustrated in the figures. Such spatially relative terms are intended to encompass different orientations of the device in use or operation in addition to the orientation depicted in the figures.

For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes illustrated in the drawings may occur. Thus, the examples described herein are not limited to the specific shapes illustrated in the drawings, but include changes in shape occurring during manufacturing.

The features of the examples described herein may be combined in various manners as will be apparent after gaining an understanding of the disclosure of this application. Further, although the examples described herein have a variety of configurations, other configurations are possible as will be apparent after gaining an understanding of the disclosure of this application.

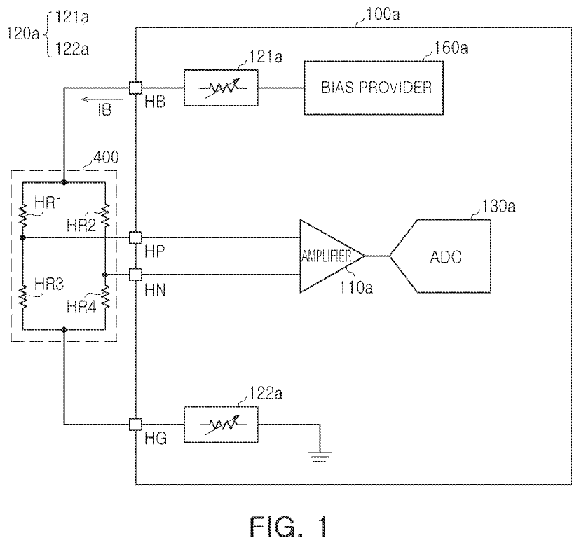

FIG. 1 is a diagram illustrating an apparatus 100a for adjusting a common mode voltage of a hall sensor, according to an example.

Referring to FIG. 1, the apparatus 100a for adjusting a common mode voltage of a hall sensor (hereafter, “apparatus”) may include, for example, a bias provider 160a and a voltage regulator 120a.

For example, the apparatus 100a may be implemented as an integrated circuit (IC), may be mounted on a substrate such as a printed circuit board, and may be electrically connected to a hall sensor 400 through the substrate. In an example, the apparatus 100a and the hall sensor 400 may be integrated into a single IC. However, the apparatus 100a and the hall sensor 400 are not limited to being implemented in the same IC.

The equivalent circuit of the hall sensor 400 may include first, second, third and fourth hall sensor resistors HR1, HR2, HR3 and HR4. A bias current IB may flow through the first, second, third and fourth hall sensor resistors HR1, HR2, HR3 and HR4. The specific structures of the first, second, third and fourth hall sensor resistors HR1, HR2, HR3 and HR4 are not limited to equivalent circuits and may be implemented in various manners.

The hall sensor 400 may sense a magnetic flux passing through the hall sensor 400 using a Hall effect. When the magnetic flux passes through the hall sensor 400, the hall sensor 400 may generate a Hall voltage in a direction perpendicular to the bias current IB and the magnetic flux, and a voltage difference between first and second hall sensor output terminals HP and HN may correspond to the Hall voltage. Accordingly, the voltage difference between the first and second hall sensor output terminals HP and HN may be used as a measurement value for the magnetic flux passing through the hall sensor 400.

For example, the closer the position of a magnetic structure (e.g., a magnet disposed on a lens module) to form a magnetic flux passing through the hall sensor 400 is to the hall sensor 400, the greater the magnetic flux passing through the hall sensor 400 is. Accordingly, a change value of the magnetic flux passing through the hall sensor 400 may be proportional to a distance moved by the magnetic structure. For example, when the magnetic flux passing through the hall sensor 400 changes by a unit magnetic flux, the voltage difference between the first and second hall sensor output terminals HP and HN may vary by a unit voltage difference.

When a reference magnetic flux is defined and a position of the magnetic structure corresponding to the reference magnetic flux is defined, a value of a difference between the magnetic flux passing through the hall sensor 400 and the reference magnetic flux may correspond to an absolute position of the magnetic structure.

For example, the reference of the voltage difference between the first and second hall sensor output terminals HP and HN corresponding to the reference magnetic flux may be set to 0,and the position of the magnetic structure may be defined as a center position.

However, due to the temperature around the hall sensor 400, the difference between the design resistance value of the hall sensor 400 and the actual resistance value, or the state of power which is the basis of the bias current IB provided to the hall sensor 400, the common mode voltage of the first and second hall sensor output terminals HP and HN, and/or the bias current IB may be changed.

The common mode voltage of the first and second hall sensor output terminals HP and HN may correspond to the average voltage of the first and second hall sensor output terminals HP and HN, and may be changed according to the average resistance value of the first, second, third and fourth hall sensor resistors HR1, HR2, HR3 and HR4 and/or the bias current IB.

When the magnetic flux passing through the hall sensor 400 changes by the unit magnetic flux, the voltage difference between the first and second hall sensor output terminals HP and HN may be proportional to a product of the unit voltage difference and the common mode voltage. Therefore, in the case in which the common mode voltage of the first and second hall sensor output terminals HP and HN is changed, the detection accuracy when detecting the magnetic flux passing through the hall sensor 400, based on the voltage difference between the first and second hall sensor output terminals HP and HN, may be degraded.

The bias provider 160a may provide the bias current IB to an input terminal HB of the hall sensor 400. For example, the bias provider 160a may be a circuit that generates the bias current IB to be robust against an external environment or process deviation. For example, the bias provider 160a may be configured as a bandgap reference circuit, and may be configured such that the bias current IB may be formed between the drain/source terminals of a transistor according to a voltage applied to a gate terminal of the transistor. For example, the bias provider 160a may be configured to receive a digital control signal and generate an analog voltage corresponding to the digital control signal, and may apply the analog voltage to the gate terminal of the transistor or some transistors of the bandgap reference circuit.

The voltage regulator 120a may include a first voltage regulator 121a and a second voltage regulator 122a. The first voltage regulator 121a may be configured such that a first voltage difference between the hall sensor 400 and the bias provider 160a, based on the bias current IB, is variable. The second voltage regulator 122a may be configured such that a second voltage difference between a ground terminal HG of the hall sensor 400 and a ground, based on the bias current IB, is variable.

The first and second voltage differences of the first and second voltage regulators 121a and 122a may be variable, such that a difference between the first voltage difference and the second voltage difference corresponds to a difference between the common mode voltage of the first and second hall sensor output terminals HP and HN of the hall sensor 400 and a reference voltage. For example, the first and second voltage differences of the first and second voltage regulators 121a and 122a may be variable, such that a value obtained by subtracting the second voltage difference from the first voltage difference increases as the common mode voltage increases.

In the case in which the common mode voltage of the first and second hall sensor output terminals HP and HN is increased, the first voltage regulator 121a may be adjusted such that the first voltage difference between the hall sensor 400 based on the bias current IB and the bias provider 160a increases, and the second voltage regulator 122a may be adjusted such that the second voltage difference between the ground terminal HG of the hall sensor 400 based on the bias current IB and the ground decreases. For example, in the case in which the common mode voltage of the first and second hall sensor output terminals HP and HN is lowered, the first voltage regulator 121a may be adjusted such that the first voltage difference between the hall sensor 400 based on the bias current IB and the bias provider 160a decreases, and the second voltage regulator 122a may be adjusted such that the second voltage difference between the ground terminal HG of the hall sensor 400 based on the bias current IB and the ground may increase. Depending on the design, only one of the first voltage difference and the second voltage difference may be adjusted, or the first voltage difference and the second voltage difference may be adjusted together.

Accordingly, the apparatus 100a for adjusting a common mode voltage of a hall sensor according to an example may adjust the common mode voltage of the first and second hall sensor output terminals HP and HN to be equal to or significantly close to the reference voltage. Therefore, detection accuracy when detecting a magnetic flux passing through the hall sensor 400 based on a voltage difference between the first and second hall sensor output terminals HP and HN may be improved.

The common mode voltage of the first and second hall sensor output terminals HP and HN may be determined based on the voltage drop of the first, second, third and fourth hall sensor resistors HR1, HR2, HR3 and HR4 based on the bias current IB. Accordingly, the common mode voltage of the first and second hall sensor output terminals HP and HN and the bias current IB may have a relatively high correlation with each other.

Therefore, the first and second voltage differences of the first and second voltage regulators 121a and 122a may be variable, such that the difference between the first voltage difference and the second voltage difference corresponds to the difference between the bias current IB and the reference current. For example, the first and second voltage differences of the first and second voltage regulators 121a and 122a may be variable, such that a value obtained by subtracting the second voltage difference from the first voltage difference increases as the bias current IB increases.

For example, in a case in which the bias current IB increases, the first voltage regulator 121a may be adjusted to increase the first voltage difference between the bias provider 160a and the hall sensor 400 based on the bias current IB, and the second voltage regulator 122a may be adjusted to decrease the second voltage difference between and a ground and the ground terminal HG of the hall sensor 400 based on the bias current IB. For example, in a case in which the bias current IB decreases, the first voltage regulator 121a may be adjusted to decrease the first voltage difference between the bias provider 160a and the hall sensor 400 based on the bias current IB, and the second voltage regulator 122a may be adjusted to increase the second voltage difference between the ground and the ground terminal HG of the hall sensor 400 based on the bias current IB. Depending on the design, only one of the first voltage difference and the second voltage difference may be adjusted, or the first voltage difference and the second voltage difference may be adjusted together.

Accordingly, the apparatus 100a may adjust the common mode voltage of the first and second hall sensor output terminals HP and HN to be equal to or significantly close to the reference voltage. Therefore, detection accuracy when detecting a magnetic flux passing through the hall sensor 400 based on a voltage difference between the first and second hall sensor output terminals HP and HN may be improved.

Referring to FIG. 1, the apparatus 100a may further include at least one of an amplifier 110a and an AD converter 130a.

The amplifier 110a may amplify a voltage difference between the first and second hall sensor output terminals HP and HN of the hall sensor 400.

For example, the amplifier 110a may be a (non) inverting amplifier circuit in which an operational amplifier and a plurality of resistors are combined, and may output an amplified voltage proportional to the voltage difference between the first and second hall sensor output terminals HP and HN. The voltage amplified by the amplifier 110a may be proportional to a voltage difference between the first and second hall sensor output terminals HP and HN.

The gain of the amplifier 110a may be determined according to the relationship between the resistance values of the plurality of resistors. It may be advantageous for the amplifier 110a to have a relatively low gain when the hall sensor 400 is required to have a wide magnetic flux sensing range, and it may be advantageous for the amplifier 110a to have a relatively high gain when the hall sensor 400 is required to have a high magnetic flux sensing resolution.

The output voltage range, gain, or efficiency of the amplifier 110a may be affected by the common mode voltage of the first and second hall sensor output terminals HP and HN. Accordingly, the amplifier 110a may be configured to optimize when the common mode voltage is the reference voltage, and the closer the common mode voltage is to the reference voltage, the wider the output voltage range may be, the more accurate gain may be, or the higher efficiency may be.

The apparatus 100a may adjust the common mode voltage, such that the common mode voltage of the first and second hall sensor output terminals HP and HN approaches the reference voltage. In addition, the output voltage range of the amplifier 110a may be widened, a gain error of the amplifier 110a may be reduced, or the efficiency of the amplifier 110a may be increased.

The AD converter 130a may be electrically connected to the output terminal of the amplifier 110a and may be configured to convert an analog value into a digital value. A digital value output from the AD converter 130a may be used to control the position of a magnetic structure (e.g., a magnet disposed on a lens module) forming a magnetic flux passing through the hall sensor 400.

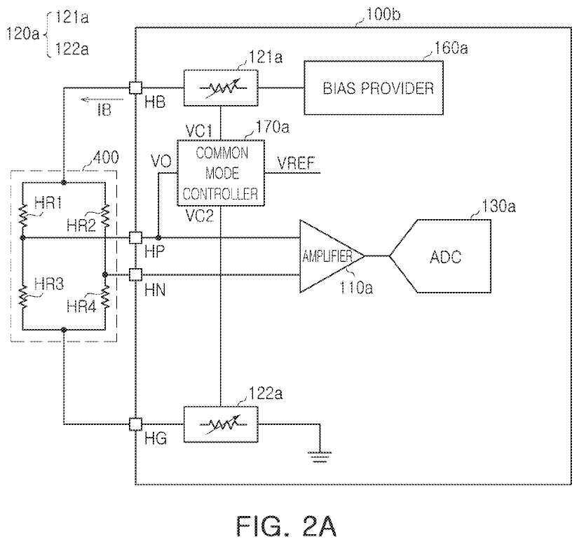

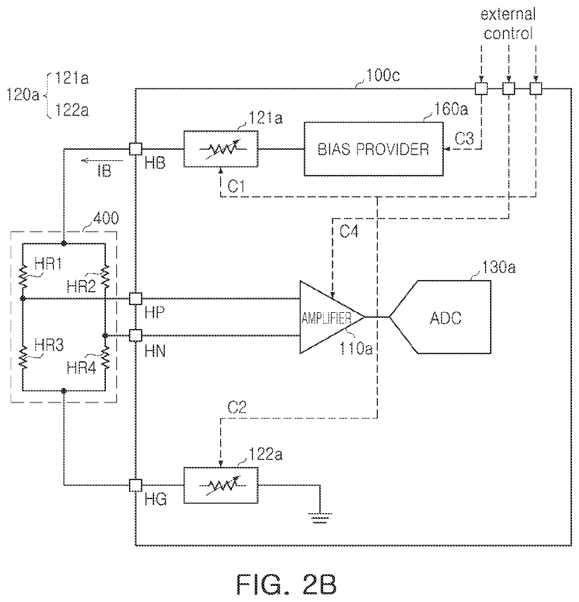

FIGS. 2A and 2B are diagrams illustrating control for the first and second voltage regulators of apparatuses 100b and 100c for adjusting a common mode voltage of a hall sensor, according to an example.

Referring to FIG. 2A, the apparatus 100b may further include a common mode controller 170a.

The common mode controller 170a may control first and second voltage differences of the first and second voltage regulators 121a and 122a, respectively, based on the common mode voltage of the first and second hall sensor output terminals HP and HN of the hall sensor 400.

For example, the common mode controller 170a may control the first and second voltage differences of the first and second voltage regulators 121a and 122a, based on a voltage VO of at least one of a first node between the first hall sensor output terminal HP and the amplifier 110a and a second node between the second hall sensor output terminal HN and the amplifier 110a. For example, the common mode controller 170a may include a switch and a sample-hold circuit to sample the voltage VO every predetermined period, and may include a buffer to accurately obtain the voltage VO, and may include a comparator for comparing the voltage VO and a reference voltage VREF.

The common mode controller 170a may generate a first control voltage VC1 and/or a second control voltage VC2, based on a difference between the voltage VO and the reference voltage VREF, may control the first voltage regulator 121a based on the first control voltage VC1, and may control the second voltage regulator 122a based on the second control voltage VC2.

In an example, the common mode controller 170a may be configured to detect the bias current IB or a voltage of the input terminal HB of the hall sensor 400, instead of the voltage VO, and may further include a current-voltage conversion circuit configured to convert a current into a voltage. For example, the common mode controller 170a may include a digital circuit such as a processor.

Referring to FIG. 2B, the apparatus 100c may receive a control signal from an external processor (e.g., a processor 270 illustrated in FIG. 7), and the control signal may include at least one of first and second control signals C1 and C2 transmitted to the first and second voltage regulators 121a and 122a, a third control signal C3 transmitted to the bias provider 160a and a fourth control signal C4 transmitted to the amplifier 110a. The first and second control signals C1 and C2 may correspond to the first and second control voltages illustrated in FIG. 2A.

The bias provider 160a may be configured such that the bias current IB is variable based on the third control signal C3. For example, the third control signal C3 is a digital value, and the bias provider 160a generates an analog voltage corresponding to the third control signal C3, and applies the analog voltage to some transistors of a bandgap reference circuit or a gate terminal of a transistor which may be included in the bias provider 160a, thereby providing the variable bias current IB. In another example, the bias provider 160a may be configured such that the bias current IB is variable based on a digital value output from the AD converter 130a.

Accordingly, the rate of change (sensitivity) of the voltage difference between the first and second hall sensor output terminals HP and HN, based on the change of the magnetic flux passing through the hall sensor 400, may be variable. When the bias current IB is changed, the common mode voltages of the first and second hall sensor output terminals HP and HN may also change.

The apparatus 100c adjusts the common mode voltage based on the difference between the first voltage difference of the first voltage regulator 121a and the second voltage difference of the second voltage regulator 122a, and thus, the common mode voltage may be adjusted without a relatively great change in the total resistance values of the first and second voltage regulators 121a and 122a. For example, the apparatus 100c may efficiently adjust the common mode voltage of the first and second hall sensor output terminals HP and HN, even when the bias current IB, which may be affected by the total resistance values of the first and second voltage regulators 121a and 122a, is controlled.

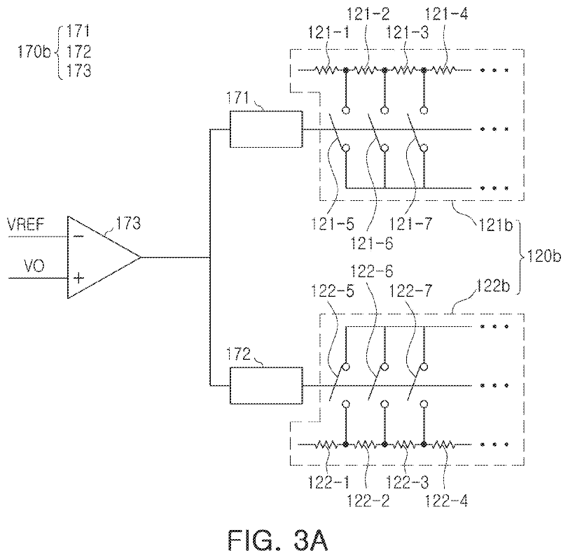

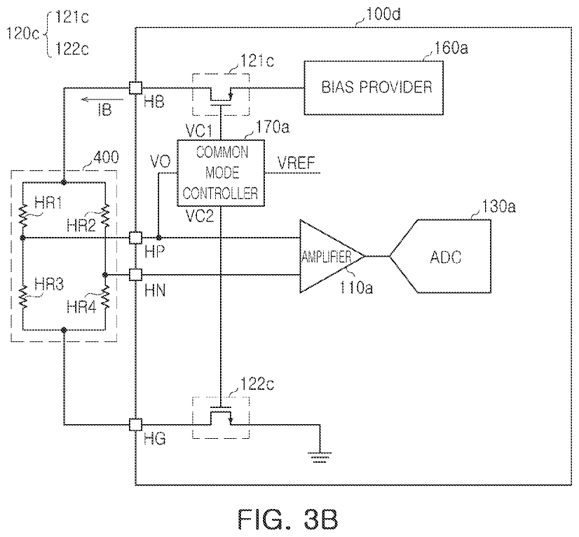

FIGS. 3A and 3B are diagrams illustrating voltage regulators 120b and 120c, respectively, of an apparatus for adjusting a common mode voltage of a hall sensor, according to examples.

Referring to FIG. 3A, the voltage regulator 120b may include first and second voltage regulators 121b and 122b, and a common mode controller 170b may include a first control voltage generator 171, a second control voltage generator 172, and a comparator 173.

The first voltage regulator 121b may include at least one first resistor 121-1, 121-2, 121-3, 121-4 connected such that a resistance value between a hall sensor and a bias provider is variable. For example, at least one of the first resistors 121-1, 121-2, 121-3 and 121-4 may have a structure in which a plurality of resistors are connected in series with each other.

The second voltage regulator 122b may include at least one second resistor 122-1, 122-2, 122-3, 122-4 connected such that a resistance value between the hall sensor and the ground is variable. For example, at least one of the second resistors 122-1, 122-2, 122-3 and 122-4 may have a structure in which a plurality of resistors are connected in series with each other.

Accordingly, the first and second voltage regulators 121b and 122b may have a structure in which power consumption is relatively low and have a simplified structure, compared to the active device, and thus, may efficiently adjust the common mode voltage of the hall sensor.

The first voltage regulator 121b may further include a plurality of first switches 121-5, 121-6 and 121-7, and the second voltage regulator 122b may further include a plurality of second switches 122-5, 122-6 and 122-7. For example, the plurality of first switches 121-5, 121-6 and 121-7 and the plurality of second switches 122-5, 122-6 and 122-7 may be respectively implemented as transistors.

For example, the plurality of first switches 121-5, 121-6 and 121-7 may be connected to one or more first resistors 121-1, 121-2, 121-3 and 121-4 in parallel, respectively, and the plurality of second switches 122-5, 122-6 and 122-7 may be connected to one or more second resistors 122-1, 122-2, 122-3 and 122-4 in parallel, respectively. As the number of first switches in the ON state among the plurality of first switches 121-5, 121-6 and 121-7 increases, a total resistance value of at least one first resistor 121-1, 121-2, 121-3, 121-4 may be lowered. As the number of second switches in the ON state among the plurality of second switches 122-5, 122-6 and 122-7 increases, a total resistance value of at least one second resistor 122-1, 122-2, 122-3, 122-4 may be lowered.

The first control voltage generator 171 may control the on/off states of the plurality of first switches 121-5, 121-6, 121-7, thereby controlling the total resistance value of at least one first resistor (121-1, 121-2, 121-3, 121-4), and may control the voltage difference between the bias provider and the hall sensor. The second control voltage generator 172 may control the on/off states of the plurality of second switches 122-5, 122-6 and 122-7, thereby controlling the total resistance value of at least one second resistor (122-1, 122-2, 122-3, 122-4), and may control the voltage difference between the hall sensor and the ground.

The comparator 173 may output a voltage corresponding to a difference between the voltage VO of the first and/or second hall sensor output terminals and the reference voltage VREF. The first control voltage generator 171 may control the first voltage regulator 121b to increase a total resistance value of at least one first resistor (121-1, 121-2, 121-3, 121-4) when the voltage VO is greater than the reference voltage VREF. The second control voltage generator 172 may control the second voltage regulator 122b to increase the total resistance value of at least one second resistor (122-1, 122-2, 122-3, 122-4) when the voltage VO is less than the reference voltage VREF.

For example, the common mode controller 170b may select one of the first and second voltage regulators 121b and 122b according to the high and low relationship between the voltage VO and the reference voltage VREF, and may change the resistance value of the selected voltage regulator. In an example, the voltage VO may be replaced with a bias current, and the reference voltage VREF may be replaced with a reference current.

In addition, the common mode controller 170b may stepwise change or stepwise activate the resistance value of the voltage regulator selected from among the first and second voltage regulators 121b and 122b.

Referring to FIG. 3B, first and second voltage regulators 121c and 122c of the voltage regulator 120c of an apparatus 100d for adjusting a common mode voltage of a hall sensor may be replaced by transistors.

Current flowing through the first and second voltage regulators 121c and 122c may be determined by a bias current IB provided by a bias provider 160a, and the voltage difference between the voltage at the drain terminal of the transistor and the voltage at the source terminal of the transistor may be determined by the voltage difference between the voltage at the gate terminal and the voltage at the source terminal of the transistor, and by the bias current IB. Accordingly, a common mode controller 170a may apply first and second control voltages VC1 and VC2 to the gate terminals of the first and second voltage regulators 121c and 122c, thereby adjusting the voltage difference between the bias provider 160a and the hall sensor 400 and adjusting the voltage difference between the hall sensor 400 and the ground.

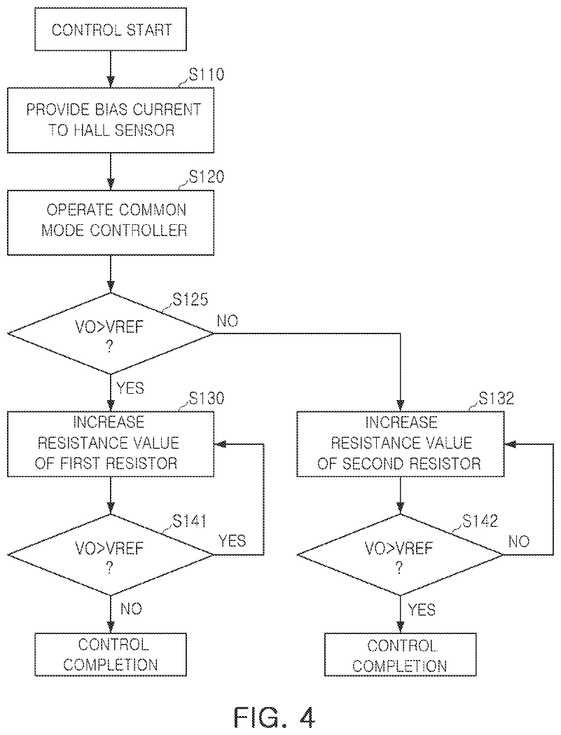

FIG. 4 is a flow chart illustrating a control process for first and second voltage regulators of an apparatus for adjusting a common mode voltage of a hall sensor, according to an example.

Referring to FIG. 4, the apparatus for adjusting a common mode voltage of a hall sensor (hereafter, “apparatus”) may provide a bias current to a hall sensor, in operation S110, and may perform common mode control in operation S120. For example, the apparatus may perform common mode control by controlling an operation of a common mode controller. In operation S125, the apparatus may compare the voltage VO of the first and/or second hall sensor output terminals of the hall sensor with the reference voltage VREF.

In operation S130, the apparatus may increase a resistance value of the first resistor of the first voltage regulator, when the voltage VO is greater than the reference voltage VREF in operation S125. Following operation S130, the apparatus may compare the voltage VO and the reference voltage VREF, in operation S141, and may stepwise increase or activate the resistance value of the first resistor of the first voltage regulator by repeatedly performing operations S130 and S141 until the voltage VO becomes less than or equal to the reference voltage VREF.

Alternatively, in operation S132, the apparatus may increase a resistance value of the second resistor of the second voltage regulator, when the voltage VO is less than the reference voltage VREF in operation S125. Following operation S132, the apparatus may compare the voltage VO and the reference voltage VREF, in operation S142, and may stepwise increase or activate the resistance value of the second resistor of the second voltage regulator by repeatedly performing operations S132 and S142 until the voltage VO is greater than or equal to the reference voltage VREF.

In an example, the voltage VO may be replaced with a bias current, and the reference voltage VREF may be replaced with a reference current.

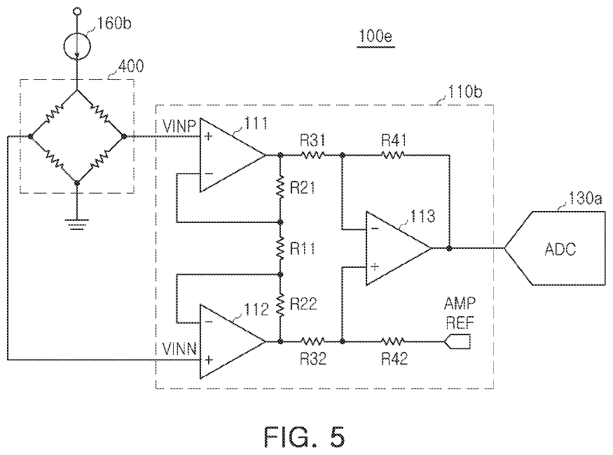

FIG. 5 is a diagram illustrating an amplifier 110b of an apparatus 110e for adjusting a common mode voltage of a hall sensor, according to an example.

Referring to FIG. 5, the apparatus 100e may include the amplifier 110b and a bias provider 160b. The amplifier 110b may include a first amplifier 111, a second amplifier 112, and a third amplifier 113. For example, the first, second, and third amplifiers 111, 112 and 113 may each be implemented as an operational amplifier (OP-AMP).

The first amplifier 111 may include a first amplifier output terminal, and a plurality of first amplifier input terminals. One of the first amplifier input terminals is electrically connected to the first amplifier output terminal, and another one (VINP) of the first amplifier input terminals is electrically connected to a first hall sensor output terminal.

The second amplifier 112 may include a second amplifier output terminal, and a plurality of second amplifier input terminals. One of the second amplifier input terminals is electrically connected to the second amplifier output terminal, and another one of the second amplifier input terminals (VINN) is electrically connected to the second hall sensor output terminal.

The third amplifier 113 may include a third amplifier output terminal, and a plurality of third amplifier input terminals. One of the third amplifier input terminals is electrically connected to the second amplifier output terminal, and another one of the third amplifier input terminals is electrically connected to the first amplifier output terminal and the third amplifier output terminal.

Accordingly, input impedance of the amplifier 110b may be greater than output impedance, and, ideally, may be infinite. As the input impedance of the amplifier 110b increases, the changes in voltages between the first and second hall sensor output terminals of the hall sensor 400, based on the electrical connection of the amplifier 110b with respect to the hall sensor 400, may decrease. Since the voltage may have a higher correlation with the magnetic flux passing through the hall sensor 400, detection accuracy when detecting the magnetic flux passing through the hall sensor 400 may be improved. In addition, since the input impedance of the amplifier 110b is relatively great, the power supply rejection ratio (PSRR) characteristics and the common mode rejection ratio (CMRR) characteristics of the amplifier 110b may be further improved, and the amplifier 110b may have greater robustness against noise.

The amplifier 110b may further include a plurality of resistors R11, R21, R22, R31, R32, R41 and R42 electrically connected to the first, second, and third amplifiers 111, 112 and 113. The output voltage range, gain, or efficiency of the amplifier 110b may be determined according to a resistance value, a resistance value ratio, or an average resistance value of at least some of the plurality of resistors R11, R21, R22, R31, R32, R41 and R42.

The amplifier 110b may receive an amplifier bias voltage AMP REF and may have an output voltage range, gain, or efficiency based on the amplifier bias voltage AMP REF.

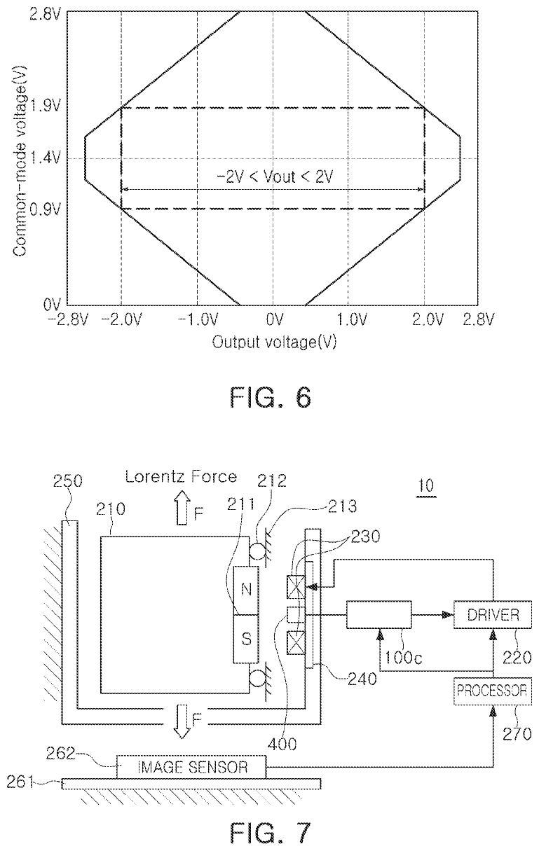

FIG. 6 is a graph illustrating a relationship between the amplifier 110b and a common mode voltage, according to an example.

Referring to FIG. 6, the amplifier 110b may be optimized to have a widest output voltage (Vout) range when the common-mode voltage is 1.4V.

The greater the difference between the common-mode voltage and the reference voltage (for example, 1.4V) is, the narrower the range of the output voltage Vout may be. For example, when the difference between the common-mode voltage and the reference voltage (e.g., 1.4V) is 0.2V or less, the range of the output voltage Vout may be about −2.6V to +2.6V. For example, when the difference between the common-mode voltage and the reference voltage (for example, 1.4V) is 0.5V, the range of the output voltage Vout may be −2.0V to +2.0V. For example, when the difference between the common-mode voltage and the reference voltage (e.g., 1.4V) is 1.4V, the range of the output voltage Vout may be about −0.4V to +0.4V.

An apparatus for adjusting a common mode voltage of a hall sensor, according to an example, may adjust the common-mode voltage, such that a common-mode voltage is equal to or significantly close (e.g., a difference of 0.2V or less) to a reference voltage (e.g., 1.4V), and thus, the range of the output voltage Vout of the amplifier illustrated in FIG. 5 may be stably widened, and the high detection accuracy, good PSRR characteristics, and CMRR characteristics of the amplifier of 110b may be stably used.

FIG. 7 is a view illustrating an apparatus 10 for controlling a lens module, according to an example.

Referring to FIG. 7, an apparatus 10 for controlling a lens module may include the apparatus 100c for adjusting a common mode voltage of a hall sensor, and may further include a driver 220, a driving coil 230, a lens module 210, and the hall sensor 400.

The driver 220 may receive an output value of the ADC 130a of the apparatus 100c, and may output the driving current based on the voltage difference (corresponding to the output value) between the first and second hall sensor output terminals HP and HN of the hall sensor 400.

For example, the driver 220 may have an Optical Image Stabilization (OIS) control structure or an Auto Focus (AF) control structure, and may include a driving circuit that generates a driving current based on an output value of the control structure. In an example, the control structure may be included in the apparatus 100c, and the apparatus 100c may be implemented as a single IC. However, the disclosure is not limited to a single IC configuration.

The driving coil 230 may receive a driving current. For example, the driving coil 230 may be disposed near a magnetic structure 211 of the lens module 210. For example, the lens module 210 may be disposed to move, based on the driving current flowing through the driving coil 230.

The lens module 210 may move according to the force received by the magnetic structure 211 in response to the magnetic flux of the driving coil 230. In this case, the lens module 210 may move to change the magnetic flux in a direction opposite to the change of the magnetic flux passing through the hall sensor 400. Accordingly, the absolute position of the lens module 210 may be substantially fixed, and an image obtained by the lens module 210 may be stable.

The hall sensor 400 may be disposed to determine a voltage difference between the first and second hall sensor output terminals HP and HN of the hall sensor 400, based on the position of the lens module 210. For example, at least one of the hall sensor 400, the driver 220, the apparatus 100c, and the driving coil 230 may be disposed on a first substrate 240.

Referring to FIG. 7, the apparatus 10 for controlling a lens module may include a processor 270 that controls first and second voltage differences between the first and second voltage regulators 121b and 122b of the apparatus 100c, based on a common mode voltage of the first and second hall sensor output terminals HP and HN of the hall sensor 400.

The processor 270 may control the bias provider 160a of the apparatus 100c, such that the bias current IB flowing through the hall sensor 400 is variable, and may control the first and second voltage differences of the first and second voltage regulators 121b and 122b, based on the bias current IB.

For example, the processor 270 may be an image signal processor (ISP), may receive image information from an image sensor 262 on a first support member 261, and may transmit the processed information to the driver 220. The processor 270 may be separated from or integrated with the ISP.

The lens module 210 may move one-dimensionally or two-dimensionally according to the rotation of a plurality of guide balls 212 on a second support member 213, and may be surrounded by a housing 250.

Although the embodiment of FIG. 7 describes an example including the apparatus 100c for adjusting a common mode voltage of a hall sensor, it is to be understood that the apparatuses for adjusting a common mode voltage of a hall sensor according to other examples disclosed herein (e.g., the apparatuses 100a, 100b, 100d, and 100e) may also be applied to the example of FIG. 7.

As set forth above, in an apparatus for adjusting a common mode voltage of a hall sensor and an apparatus for controlling a lens module, according to an example, the accuracy of position detection of a magnetic structure (e.g., a magnet disposed on a lens module that forms a magnetic flux passing through the hall sensor may be improved, and the performance of components (e.g., an amplifier, an AD converter, and a bias provider) that may be adapted to a common mode voltage of the hall sensor may be improved, or the design freedom of the components may be increased.

The common mode controller 170a and the processor 270 in FIGS. 1 to 7 that perform the operations described in this application are implemented by hardware components configured to perform the operations described in this application that are performed by the hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1 to 7 that perform the operations described in this application are performed by computing hardware, for example, by one or more processors or computers, implemented as described above executing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions in the specification, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access memory (RAM), flash memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. An apparatus with hall sensor common mode voltage adjustment, comprising:
a bias provider configured to provide a bias current to a hall sensor;
a first voltage regulator configured to vary a first voltage difference between the hall sensor and the bias provider, based on the bias current; and
a second voltage regulator configured to vary a second voltage difference between the hall sensor and a ground, based on the bias current,
wherein the first and second voltage differences are variable such that a difference between the first voltage difference and the second voltage difference corresponds to a difference between a common mode voltage of first and second hall sensor output terminals of the hall sensor and a reference voltage.

2. The apparatus of claim 1, wherein the first and second voltage differences are variable such that a value obtained by subtracting the second voltage difference from the first voltage difference increases as the common mode voltage of the of first and second hall sensor output terminals increases.

3. The apparatus of claim 1, further comprising an amplifier configured to amplify a voltage difference between the first and second hall sensor output terminals,
wherein the amplifier includes:
a first amplifier including a first amplifier output terminal, a first amplifier input terminal electrically connected to the first amplifier output terminal, and another first amplifier input terminal electrically connected to the first hall sensor output terminal;
a second amplifier including a second amplifier output terminal, a second amplifier input terminal electrically connected to the second amplifier output terminal, another second amplifier input terminal electrically connected to the second hall sensor output terminal; and
a third amplifier including a third amplifier output terminal, a third amplifier input terminal electrically connected to the second amplifier output terminal, and another third amplifier input terminal electrically connected to the first amplifier output terminal and the third amplifier output terminal.

4. The apparatus of claim 1, further comprising:
an amplifier configured to amplify a voltage difference between the first and second hall sensor output terminals; and
a common mode controller configured to control the first and second voltage differences, based on a voltage of either one or both of a node between the first hall sensor output terminal and the amplifier, and a node between the second hall sensor output terminal and the amplifier.

5. The apparatus of claim 1, further comprising a common mode controller configured to control the first and second voltage differences, based on the common mode voltage of the first and second hall sensor output terminals.

6. The apparatus of claim 5, wherein the common mode controller is further configured to:
determine a voltage difference to be changed, among the first voltage difference and the second voltage difference, according to a high and low relationship between the common mode voltage of the first and second hall sensor output terminals and the reference voltage; and
stepwise adjust a voltage difference of a voltage regulator corresponding to a predetermined voltage difference, among the first and second voltage regulators.

7. The apparatus of claim 1, wherein the first voltage regulator includes at least one first resistor connected such that a resistance value between the hall sensor and the bias provider is variable, and
wherein the second voltage regulator includes at least one second resistor connected such that a resistance value between the hall sensor and the ground is variable.

8. An apparatus with lens module control, comprising:
the apparatus with hall sensor common mode voltage adjustment of claim 1;
a driver configured to output a driving current, based on a voltage difference between the first and second hall sensor output terminals;
a driving coil configured to receive the driving current;
a lens module configured to move based on the driving current, as the driving current flows through the driving coil; and
the hall sensor,
wherein the hall sensor is configured to determine the voltage difference between the first and second hall sensor output terminals, based on a position of the lens module.

9. The apparatus with lens module control of claim 8, further comprising a processor configured to control first and second voltage differences of the first and second voltage regulators, based on the common mode voltage of first and second hall sensor output terminals.

10. The apparatus with lens module control of claim 8, further comprising a processor configured to control the bias provider such that the bias current is variable and control first and second voltage differences, based on the bias current.

11. An apparatus with hall sensor common mode voltage adjustment, comprising:
a bias provider configured to provide a bias current to a hall sensor;
a first voltage regulator configured to vary a first voltage difference between the hall sensor and the bias provider, based on the bias current; and
a second voltage regulator configured to vary a second voltage difference between the hall sensor and a ground, based on the bias current,
wherein the first and second voltage differences are variable such that a difference between the first voltage difference and the second voltage difference corresponds to a difference between the bias current and a reference current.

12. The apparatus of claim 11, wherein the first and second voltage differences are variable such that a value obtained by subtracting the second voltage difference from the first voltage difference increases as the bias current increases.

13. The apparatus of claim 12, further comprising:
an amplifier configured to amplify a voltage difference between first and second hall sensor output terminals of the hall sensor; and
an AD converter electrically connected to an output terminal of the amplifier, and configured to convert an analog value into a digital value and output the digital value,
wherein the bias provider is further configured to vary the bias current, based on the digital value.

14. The apparatus of claim 11, further comprising an amplifier configured to amplify a voltage difference between first and second hall sensor output terminals of the hall sensor,
wherein the amplifier includes:
a first amplifier including a first amplifier output terminal, a first amplifier input terminal electrically connected to the first amplifier output terminal, and another first amplifier input terminal electrically connected to the first hall sensor output terminal;
a second amplifier including a second amplifier output terminal, a second amplifier input terminal electrically connected to the second amplifier output terminal, and another second amplifier input terminal electrically connected to the second hall sensor output terminal; and
a third amplifier including a third amplifier output terminal, a third amplifier input terminal electrically connected to the second amplifier output terminal, another third amplifier input terminal electrically connected to the first amplifier output terminal and the third amplifier output terminal.

15. The apparatus of claim 11, wherein the first voltage regulator includes at least one first resistor connected such that a resistance value between the hall sensor and the bias provider is variable, and
wherein the second voltage regulator includes at least one second resistor connected such that a resistance value between the hall sensor and the ground is variable.

16. The apparatus of claim 15, further comprising a common mode controller configured to control the first and second voltage differences of the first and second voltage regulators,
wherein the at least one first resistor includes a plurality of first resistors,
wherein the at least one second resistor includes a plurality of second resistors, and
wherein the common mode controller is further configured to determine a voltage difference to be changed, among the first voltage difference and the second voltage difference, according to a high and low relationship between the bias current and the reference current, and stepwise activate a plurality of resistors corresponding to a predetermined voltage difference among the plurality of first resistors and the plurality of second resistors.

17. An apparatus with lens module control, comprising:
the apparatus with hall sensor common mode voltage adjustment of claim 11;
a driver configured to output a driving current, based on a voltage difference between the first and second hall sensor output terminals;
a driving coil configured to receive the driving current;
a lens module configured to move based on the driving current, as the driving current flows through the driving coil; and
the hall sensor,
wherein the hall sensor is disposed to determine the voltage difference between the first and second hall sensor output terminals, based on a position of the lens module.

18. The apparatus with lens module control of claim 17, further comprising a processor configured to control the first and second voltage differences, based on the common mode voltage of the first and second hall sensor output terminals.

19. The apparatus with lens module control of claim 17, further comprising a processor configured to control the bias provider such that the bias current is variable and control first and second voltage differences, based on the bias current.

20. An apparatus with hall sensor common mode voltage adjustment, comprising:
a bias provider configured to provide a bias current to a hall sensor;
a first voltage regulator configured to provide a first voltage difference between the hall sensor and the bias provider, based on the bias current;
a second voltage regulator configured to provide a second voltage difference between the hall sensor and a ground, based on the bias current; and
a controller configured to control either one or both of the first voltage regulator and the second voltage regulator to vary a difference between the first voltage difference and the second voltage difference, based on a common mode voltage of first and second hall sensor output terminals of the hall sensor.

21. The apparatus of claim 20, wherein the first voltage regulator comprises a first variable resistance element and the second voltage regulator comprises a second variable resistance element, and
wherein the controller is further configured to vary a total resistance of either one or both of the first variable resistance element and the second variable resistance element.

22. The apparatus of claim 20, wherein first voltage regulator comprises a first transistor and the second voltage regulator comprises a second transistor, and
wherein the controller is further configured to vary either one or both of a control voltage applied to the first transistor and a control voltage applied the second transistor.

23. The apparatus of claim 20, wherein the controller is further configured to control the first voltage regulator to increase the first voltage difference and/or control the second voltage regulator to decrease the second voltage difference, in response to the common mode voltage of first and second hall sensor output terminals increasing, and
wherein the controller is further configured to control the first voltage regulator to decrease the first voltage difference and/or control the second voltage regulator to increase the second voltage difference, in response to the common mode voltage of first and second hall sensor output terminals decreasing.
